(19) United States
(12) Patent Application Publication
(10) Pub. No.: US 2026/0297384 A1
(43) Pub. Date: Oct. 1, 2026

(54) POLISHING SLURRY, POLISHING SYSTEM, AND METHOD FOR POLISHING SEMICONDUCTOR SUBSTRATE

(71) Applicant: FUJIMI INCORPORATED, Aichi (JP)

(72) Inventors: Sheng-Han Chen, Miaoli County (TW); Ying-Chieh Chao, Miaoli County (TW)

(21) Appl. No.: 19/573,632

(22) Filed: Mar. 20, 2026

(30) Foreign Application Priority Data
Mar. 25, 2025 (JP) 2025-049815

(51) Int. Cl. C09G 1/02; B24B 37/24; H10P 52/40; H10P 72/00

(52) U.S. Cl. CPC C09G 1/02; B24B 37/24; H10P 52/407; H10P 72/0428

(57) ABSTRACT

There are provided a polishing slurry, a polishing system, and a polishing method for a substrate including an aluminum nitride film to be polished. The polishing slurry contains negatively charged abrasive grains and an organic acid compound. The polishing system includes a polishing pad and a polishing slurry. The polishing method includes the steps of: bringing a substrate including an aluminum nitride film into contact with a polishing pad; preparing a polishing slurry; and polishing the substrate including an aluminum nitride film while simultaneously supplying the polishing slurry to the substrate including an aluminum nitride film.

### TECHNICAL FIELD

The present disclosure relates to a polishing slurry, a polishing system, and a method for polishing a semiconductor substrate, and particularly to a polishing slurry, a polishing system, and a method for polishing a semiconductor substrate for a substrate including an aluminum nitride film to be polished.

### BACKGROUND ART

In the current semiconductor industry, in order to remove excess material or to provide a completely planar underlying surface for an upper layer circuit structure, planarization techniques are normally used to increase the flatness of a semiconductor substrate surface or a wafer surface. The planarization techniques include thermal reflow, an etch-back method, a chemical mechanical polishing (CMP) process, and the like. The thermal reflow and etch-back method can achieve local planarization of a semiconductor substrate surface or a wafer surface, and the CMP has an effect of planarizing a semiconductor substrate surface or a wafer surface over an entire surface thereof. The CMP technique achieves the purpose of planarization by removing all materials and irregular structures on a semiconductor substrate surface or a wafer surface using a polishing slurry having polishing properties and corrosive properties together with a polishing pad and a polishing head.

Components of a polishing slurry used in the planarization process (CMP process) vary depending on the polishing target. That is, polishing slurries used for different polishing targets may each have different components. In order to increase the removal rate (also referred to as polishing removal rate) for a polishing target in the CMP process and to reduce surface roughness of the polishing target after the CMP process, there is a need for the presence of a new polishing slurry, a polishing system, and a polishing method.

### SUMMARY

### Technical Problem

An object of the present disclosure is to provide a polishing slurry, a polishing system, and a polishing method that have a high removal rate for aluminum nitride (AlN) and are capable of reducing surface roughness of an aluminum nitride film after polishing.

### Solution to Problem

In order to achieve the above object, one aspect of the present disclosure provides a polishing slurry for a substrate including an aluminum nitride film to be polished. The polishing slurry contains negatively charged abrasive grains and an organic acid compound.

In order to achieve the above object, another aspect of the present disclosure provides a polishing system for a substrate including an aluminum nitride film to be polished. The polishing system includes a polishing pad and a polishing slurry. The polishing slurry contains negatively charged abrasive grains and an organic acid compound.

Another aspect of the present disclosure further provides a method for polishing a semiconductor substrate that can achieve the above object. The polishing method includes the steps of: providing a substrate including an aluminum nitride film; bringing the substrate including an aluminum nitride film into contact with a polishing pad; producing a polishing slurry; and polishing the substrate including an aluminum nitride film using the polishing slurry. The polishing slurry contains negatively charged abrasive grains and an organic acid compound.

### BRIEF DESCRIPTION OF THE DRAWING

By reading the detailed description and embodiments of the present disclosure in combination with the drawing, the object of the present disclosure will become more apparent and more easily understood.

FIG. 1 is a flowchart of a method for polishing a semiconductor substrate according to an embodiment of the present disclosure.

### DESCRIPTION OF EMBODIMENTS

One aspect of the present disclosure provides a polishing slurry for a substrate including an aluminum nitride film to be polished. The polishing slurry contains negatively charged abrasive grains and an organic acid compound.

Another aspect of the present disclosure provides a polishing system for a substrate including an aluminum nitride film to be polished. The polishing system includes a polishing pad and a polishing slurry. The polishing slurry contains negatively charged abrasive grains and an organic acid compound.

Another aspect of the present disclosure further provides a method for polishing a semiconductor substrate. The polishing method includes the steps of: providing a substrate including an aluminum nitride film; bringing the substrate including an aluminum nitride film into contact with a polishing pad; producing a polishing slurry; and polishing the substrate including an aluminum nitride film using the polishing slurry. The polishing slurry contains negatively charged abrasive grains and an organic acid compound.

The polishing slurry, the polishing system, and the polishing method of the present disclosure have a high removal rate for aluminum nitride, while simultaneously reducing surface roughness of an aluminum nitride film after polishing.

The following description is intended to explain the basic principles of the present disclosure and should not be construed as limiting. The scope of the present disclosure is determined with reference to the claims. Hereinafter, exemplary embodiments of the present disclosure (an example of which is shown in the drawing) will be described in detail. As much as possible, the same reference signs used in the drawing and the description denote the same or similar members.

It should be further understood that, as used herein, the terms “comprising” and/or “including” indicate the presence of characteristic members, integers, steps, operations, elements, components, and/or groups thereof, but do not exclude the presence or addition of one or more other characteristic members, integers, steps, operations, elements, components, and/or groups thereof. As used herein, the singular form “one” is intended to include the plural form as well, unless the context clearly indicates otherwise.

An additional step/stage may be added before, during, and/or after a plurality of steps/stages described in the method of the present disclosure. Some of the steps/stages may be replaced or omitted in different embodiments. Although some of the embodiments described are conducted in a particular order of steps/stages, these steps/stages may also be conducted in a different order that is reasonable.

In the present disclosure, unless otherwise specifically stated, the terms “about”, “equal to”, “equal” or “the same”, and “substantially” or “approximately” normally refer to values that vary within 20% of a predetermined value or range, or values that vary within 10%, within 5%, within 3%, within 2%, within 1%, or within 0.5% of a predetermined value or range. As used herein, the expression “a to b” or “from a to b” used for representing a specific numerical range are defined as “≥a and ≤b”. As used herein, the expression “more than a” used for representing a specific numerical range is defined as “>a” and does not include a, and the expression “less than b” is defined as “<b” and does not include b. In addition, as used herein, “weight” and “mass”, “% by weight” and “% by mass”, and “parts by weight” and “parts by mass” are treated as synonyms. In the present specification, unless otherwise noted, operations and measurements of physical properties or other factors are carried out under conditions of room temperature (20° C. or higher and 25° C. or lower)/relative humidity of 40% RH or more and 50% RH or less.

Unless otherwise defined, all terms used herein (including technical and scientific terms) have the same meanings as those normally understood by those skilled in the art. Unless specifically defined in the embodiments of the present disclosure, these terms, for example, terms defined in normally used dictionaries, should be understood to have meanings consistent with the relevant technology and the background or context of the present disclosure, and should not be interpreted in an idealized or overly formal manner.

One embodiment of the present disclosure provides a polishing slurry used for polishing a substrate including an aluminum nitride film. The polishing slurry may be of a single-fluid type or multi-fluid type including double-fluid type. Also, in some embodiments, the polishing slurry may be in the form of a concentrated stock solution. In embodiments where the polishing slurry is a concentrated stock solution, the polishing slurry can be diluted, for example, 2 to 10 times or more with a diluent such as water before polishing the substrate including an aluminum nitride film.

The substrate including an aluminum nitride film of the present disclosure may have a single-layer structure or may have a multilayer structure including a plurality of layers. In embodiments where the substrate including an aluminum nitride film has a single-layer structure, the substrate including an aluminum nitride film may be an aluminum nitride substrate. In embodiments where the substrate including an aluminum nitride film has a multilayer structure, the substrate including an aluminum nitride film may include a base, or an aluminum nitride film disposed on a base, but the present disclosure is not limited thereto. In some embodiments, in the substrate including an aluminum nitride film, a base may be present on the surface together with an aluminum nitride film. In these embodiments, the base may further include a through-hole penetrating the base in the normal direction of the base, a driving circuit, and/or a compensation circuit, but the present disclosure is not limited thereto. The base may include a transparent or opaque, organic or inorganic material, and may include a hard material or a flexible material. Examples of the organic material may include polyimide (PI), polycarbonate (PC), polyethylene terephthalate (PET), liquid crystal polymer (LCP), other known suitable materials, and a combination thereof, but the present disclosure is not limited thereto. Examples of the inorganic material may include dielectric materials or metallic materials, but the present disclosure is not limited thereto. Examples of the hard material may include glass, quartz, sapphire, ceramics, plastics, or any suitable materials. As used herein, the “flexible material” refers to a material capable of being curved, bent, folded, rolled, warped (flexible), stretched, and/or otherwise deformed in a similar manner. Examples of the flexible material may include one of the above-described organic materials, but the flexible material in the present disclosure is not restricted to the materials described above.

The aluminum nitride film is not particularly restricted, but may be, for example, a film produced by a physical vapor deposition (PVD) method. Although the thickness of the aluminum nitride film is not particularly restricted, it may be, for example, 1000 to 100000 Å.

The polishing slurry of the present disclosure contains negatively charged abrasive grains and an organic acid compound. Hereinafter, the components of the polishing slurry of the present disclosure will be described.

### <Negatively Charged Abrasive Grains>

In embodiments of the present disclosure, the abrasive grains have a negative zeta potential. According to such embodiments, particularly in an acidic region, the polishing removal rate (also referred to as removal rate or polishing rate) for a polishing target having a positive zeta potential can be increased.

In some embodiments, the negatively charged abrasive grains may be surface-modified, negatively charged abrasive grains. The modified, negatively charged abrasive grains can be obtained by, for example, mixing a metal such as aluminum, titanium, or zirconium, or an oxide thereof, with negatively charged abrasive grains and doping it onto the surface of the negatively charged abrasive grains, or by immobilizing an organic acid on the surface of the negatively charged abrasive grains. In preferred embodiments, the modified, negatively charged abrasive grains are abrasive grains in which an organic acid is immobilized on the surface of the negatively charged abrasive grains. In more preferred embodiments, the modified, negatively charged abrasive grains are silica in which an organic acid is chemically bonded to the surface thereof. In some embodiments, the modified, negatively charged abrasive grains are silica in which an acidic group derived from an organic acid is fixed on the surface thereof by covalent bonding (in some cases, via a linker). Here, the linker refers to any structure interposed between the surface of the silica and the organic acid. That is, in some embodiments, an acidic group derived from an organic acid may be directly fixed on the surface of the silica by covalent bonding, or may be fixed by covalent bonding via a linker. The method for introducing this organic acid onto the silica surface is not particularly restricted. In some embodiments, the organic acid can be introduced onto the silica surface by a method in which the organic acid group having a protecting group bonded thereto is introduced onto the silica surface and the protecting group is then removed. The organic acid is not particularly restricted, and examples thereof include sulfonic acid, carboxylic acid, and phosphoric acid, with sulfonic acid being preferable. In some embodiments, the negatively charged abrasive grains may include sulfonic acid-modified silica in which sulfonic acid is immobilized on the surface of silica. In these embodiments, sulfonic acid can be fixed on the surface of silica by, for example, the method described in “Sulfonic acid-functionalized silica through quantitative oxidation of thiol groups”, Chem. Commun. 246-247 (2003). Specifically, silica having sulfonic acid immobilized on the surface thereof can be obtained by coupling a silane coupling agent having a thiol group, such as 3-mercaptopropyltrimethoxysilane, to silica, followed by oxidation of the thiol group with hydrogen peroxide. Colloidal silica, the surface of which is modified with sulfonic acid, can also be manufactured in the same manner. In some embodiments, the negatively charged abrasive grains may include carboxylic acid-modified silica in which carboxylic acid is immobilized on the surface of silica. In these embodiments, carboxylic acid can be fixed on the surface of silica by, for example, the method described in “Novel Silane Coupling Agents Containing a Photo labile 2-Nitrobenzyl Ester for Introduction of a Carboxy Group on the Surface of Silica Gel”, Chemistry Letters, 3, 228-229 (2000). Specifically, silica having carboxylic acid immobilized on the surface thereof can be obtained by coupling a silane coupling agent containing a photoreactive 2-nitrobenzyl ester to silica, followed by photoirradiation. Compared with unmodified silica, the modified silica can provide a higher aluminum nitride removal rate.

In some embodiments where the negatively charged abrasive grains are silica, the silica particles have silanol groups on the surface thereof. The term “silanol group” as used herein refers to hydroxy groups directly bonded to silicon atoms on the surface of the silica particles. The steric configuration or steric coordination of the silanol groups is not particularly limited, and the conditions for producing the silanol groups are not particularly limited either. The term “silanol group density” as used herein refers to the number of silanol groups per unit surface area of the silica particle surface. The silanol group density can represent electrical characteristics or chemical characteristics of the silica particle surface. In these embodiments, the silanol group density of the negatively charged abrasive grains may be 0 to 20.0 groups/nm², but the present disclosure is not limited thereto. In some embodiments, the silanol group density of the negatively charged abrasive grains may be 0.5 to 15.0 groups/nm², 1.0 to 10.0 groups/nm², 2.0 to 8.0 groups/nm², 4.0 to 7.0 groups/nm², or 5.0 to 6.0 groups/nm². When the negatively charged abrasive grains have a silanol group density within the above range, the polishing slurry can exhibit favorable polishing characteristics and can also have improved stability.

Here, the shape of the negatively charged abrasive grains is not particularly limited, and may be spherical shape, non-spherical shape, or irregular shape. Examples of the non-spherical shape may include a polygonal columnar shape (for example, a triangle pole shape or a square pole shape), a cylindrical shape, a straw bag shape in which the center part of the cylinder is swollen more than the end parts, a ring shape (donut shape) in which the center part of a disk is hollow, a plate shape, a cocoon type shape having a constriction at the center part, an associated type spherical shape in which a plurality of particles are integrated, a kompeito shape having a plurality of protrusions on the surface, and a rugby ball shape, but the present disclosure is not limited thereto.

The size of the negatively charged abrasive grains is not particularly limited. In some embodiments, images obtained using a scanning electron microscope (SEM) are observed, and the average primary particle size of the negatively charged abrasive grains is calculated based on the images. The average primary particle size of the negatively charged abrasive grains is, for example, 1 nm or more, 10 nm or more, 20 nm or more, or 30 nm or more. In some embodiments, the average primary particle size of the negatively charged abrasive grains is 100 nm or less, 80 nm or less, 65 nm or less, 50 nm or less, or 40 nm or less. In some embodiments, the negatively charged abrasive grains aggregate in the polishing slurry to form secondary particles. The average secondary particle size of the secondary particles can be measured by a dynamic light scattering method, including a laser diffraction/scattering method. In some embodiments, the average secondary particle size of the secondary particles may be 10 nm or more, 20 nm or more, 40 nm or more, 50 nm or more, or 60 nm or more. In some embodiments, the average secondary particle size of the secondary particles may be 200 nm or less, 150 nm or less, 120 nm or less, 90 nm or less, or 80 nm or less. The negatively charged abrasive grains having the above-described average primary particle size and/or average secondary particle size can reduce the likelihood that surface defects such as scratches occur on the surface of a substrate including an aluminum nitride film when polishing is carried out using the polishing slurry. Here, the silanol group density of the negatively charged abrasive grains in the polishing slurry is calculated and determined based on the specific surface area measured by a BET method and the amount of silanol groups measured by titration. For example, the average silanol group density (unit: groups/nm²) on the surface of silica (abrasive grains) is calculated using a Sears titration method of neutralization titration described by G. W. Sears in Analytical Chemistry, vol. 28, No. 12, 1956, pp. 1982-1983.

In some embodiments, the degree of association of the negatively charged abrasive grains (average secondary particle size/average primary particle size) is preferably 1.6 or more, and more preferably 1.8 or more. Also, in some embodiments, the degree of association of the negatively charged abrasive grains (average secondary particle size/average primary particle size) is preferably 4.5 or less, more preferably 3.0 or less, still more preferably 2.7 or less, even more preferably 2.6 or less, and may be 2.5 or less, may be 2.4 or less, may be 2.3 or less, or may be 2.2 or less. In these embodiments, the average primary particle size of the negatively charged abrasive grains is particularly preferably 6 nm or more. When the degree of association of the negatively charged abrasive grains is within the above range, the effects of the present disclosure can be efficiently achieved.

The content (concentration) of the negatively charged abrasive grains in the polishing slurry of the present disclosure is not particularly limited. In some embodiments, the content of the negatively charged abrasive grains in the polishing slurry may be 0.1 to 10% by mass with respect to 100% by mass of the total mass of the polishing slurry, but the present disclosure is not limited thereto. In some embodiments, the polishing slurry may contain the negatively charged abrasive grains in an amount of 0.3 to 7% by mass, 0.8 to 2% by mass, about 1% by mass, about 1.5% by mass, or about 2% by mass, with respect to 100% by mass of the total mass of the polishing slurry. As the content of the negatively charged abrasive grains in the polishing slurry increases, the removal rate of the polishing slurry for an aluminum nitride film increases. As the content of the negatively charged abrasive grains in the polishing slurry decreases, the surface defect rate of an aluminum nitride film after polishing using the polishing slurry decreases. When the content of the negatively charged abrasive grains in the polishing slurry is within the above range, the polishing slurry can maintain a low surface defect rate of an aluminum nitride film after polishing while simultaneously increasing the removal rate for the aluminum nitride film, thereby exhibiting favorable polishing characteristics.

### <Organic Acid Compound>

The organic acid compound may include an organic acid salt. In some embodiments, the organic acid compound may include a metal salt thereof. In some embodiments, the organic acid compound may include an ammonium salt or a sodium salt. In preferred embodiments, the organic acid compound may include an ammonium salt or a potassium salt. In still more preferred embodiments, the organic acid compound may include an ammonium salt. In some embodiments, the organic acid compound may include a carboxylic acid salt. That is, the organic acid compound in the polishing slurry of the present disclosure may include at least one carboxyl group, but the present disclosure is not limited thereto. In some embodiments, the organic acid compound may contain at least two carboxyl groups or at least three carboxyl groups. In preferred embodiments, the organic acid compound is a salt of a dicarboxylic acid or a salt of a tricarboxylic acid, and more preferably a salt of a tricarboxylic acid. In some embodiments, the organic acid compound in the polishing slurry of the present disclosure may include, without limitation, an ammonium carboxylate, a potassium carboxylate, or a combination thereof. In preferred embodiments, the organic acid compound is an ammonium salt of a dicarboxylic acid or an ammonium salt of a tricarboxylic acid, and more preferably an ammonium salt of a tricarboxylic acid. In some embodiments, the organic acid compound in the polishing slurry of the present disclosure may include ammonium citrate tribasic, diammonium hydrogen citrate, ammonium dihydrogen citrate, potassium citrate, or a combination thereof. Among these, ammonium citrate tribasic, diammonium hydrogen citrate, and ammonium dihydrogen citrate, which do not include a sodium salt, are preferable, and ammonium citrate tribasic is preferable in view of quality control and the like. It should be noted that the organic acid compound does not include a pH adjusting agent described below. The organic acid compound is a compound different from the pH adjusting agent described below.

The content (concentration) of the organic acid compound is not particularly limited, and the content of the organic acid compound in the polishing slurry may be 0.01 to 3% by mass with respect to 100% by mass of the total mass of the polishing slurry, but the present disclosure is not limited thereto. In some embodiments, the polishing slurry may contain the organic acid compound in an amount of 0.02 to 2.0% by mass, 0.04 to 1.0% by mass, 0.06 to 0.5% by mass, 0.08 to 0.3% by mass, 0.1 to 0.2% by mass, about 0.08% by mass, about 0.1% by mass, or about 0.2% by mass, with respect to 100% by mass of the total mass of the polishing slurry. When an aluminum nitride film is polished using a polishing slurry containing an organic acid compound as described above in an organic acid compound content as described above, the surface roughness of the aluminum nitride film after polishing can be reduced. That is, it becomes possible to make the surface of the aluminum nitride film after polishing using the above-described polishing slurry smoother and/or flatter.

### <pH Adjusting Agent>

The polishing slurry may further contain a pH adjusting agent. That is, a preferred embodiment of the present disclosure is a polishing slurry for a substrate including an aluminum nitride film to be polished, the polishing slurry containing negatively charged abrasive grains, an organic acid compound, and a pH adjusting agent. The pH adjusting agent is not particularly limited, as long as it can adjust the pH value of the polishing slurry of the present disclosure to a desired range. The pH adjusting agent may be an acid or an alkali. Examples of the acidic pH adjusting agent may include an inorganic acid, an organic acid, and a combination thereof. Examples of the inorganic acid may include sulfuric acid, nitric acid, boric acid, carbonic acid, hypophosphorous acid, phosphorous acid, and phosphoric acid, but the present disclosure is not limited thereto. Examples of the organic acid may include 1-hydroxyethylidene-1,1-diphosphonic acid (HEDP), formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-pentanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, methanesulfonic acid, benzenesulfonic acid, and 10-camphorsulfonic acid, but the present disclosure is not limited thereto. Examples of the alkaline pH adjusting agent may include a hydroxide of an alkali metal, a quaternary ammonium salt of an alkali metal, an amine, and a combination thereof, but the present disclosure is not limited thereto. In some embodiments, the pH adjusting agent may include a monocarboxylic acid. In some embodiments, the monocarboxylic acid (for example, acetic acid) can provide a superior removal rate for an aluminum nitride film compared with nitric acid, malonic acid, and/or citric acid. In some embodiments, the pH adjusting agent may include acetic acid. The pH adjusting agent may be used alone, or two or more thereof may be used in combination. Also, the pH adjusting agent may be used as it is, or may be used in the form of an aqueous solution. It should be noted that the pH adjusting agent does not include the above-described organic acid compound. The pH adjusting agent is a compound different from the above-described organic acid compound.

The amount (concentration) of the pH adjusting agent to be added can be selected as appropriate, for example, so that the pH value of the polishing slurry is more than 4 and 8 or less. The aluminum nitride film surface generates a positive charge under conditions where the pH value is more than 4 and 8 or less, particularly in an acidic solution. That is, when an aluminum nitride film comes into contact with a polishing slurry having a pH value of more than 4 and 8 or less, the aluminum nitride film surface generates a positive charge, and under such circumstances, the negatively charged abrasive grains in the polishing slurry are adsorbed onto the positively charged aluminum nitride film surface, thereby increasing the removal rate of the polishing slurry for the aluminum nitride film.

Also, from the viewpoint of reducing surface roughness, the range of pH of the polishing slurry is preferably 5 or more and 7.5 or less, and still more preferably 5.5 or more and 7.0 or less.

Furthermore, when the pH is within the range of 5.5 or more and 6.5 or less, a high polishing removal rate (high polishing rate) for aluminum nitride and low surface roughness are balanced, which is preferable.

### <Hydrophilic Polymer>

In some embodiments, the polishing slurry of the present disclosure may further contain a hydrophilic polymer. The hydrophilic polymer is effective in reducing the surface roughness of an aluminum nitride film after polishing (post-Ra), or in reducing surface defects on an aluminum nitride film after polishing.

The hydrophilic polymer may have at least one hydrophilic side chain group. The hydrophilic side chain group is not particularly limited, and it is preferable that the hydrophilic polymer be one that can form an etching suppression layer on the aluminum nitride film surface. In some embodiments, examples of the hydrophilic side chain group may include a hydroxy group, an acryloyl group (H₂C═CH—C(═O)—), a methacryloyl group (H₂C═C(CH₃)—C(═O)—), an acryloyloxy group (H₂C═CH—C(═O)—O—), a methacryloyloxy group (H₂C═C(CH₃)—C(═O)—O—), a sulfonic acid group (—SO₃H), a pyrrolidone group, a caprolactam group, and a combination thereof, but the present disclosure is not limited thereto. In preferred embodiments, the at least one hydrophilic side chain group includes a hydroxy group, an acryloyl group, a sulfonic acid group, a pyrrolidone group, a caprolactam group, or a combination thereof.

In some embodiments, the hydrophilic side chain group may include a pyrrolidone group, a caprolactam group, or a combination thereof.

In some embodiments, the hydrophilic polymer may include polyvinylpyrrolidone, polyvinylcaprolactam, or a combination thereof.

In some embodiments, the hydrophilic polymer may include polyacrylic acid, polyvinyl alcohol, or polyvinyl alcohol partially substituted with a sulfonic acid group. In the polyvinyl alcohol partially substituted with a sulfonic acid group, for example, 1 to 10 mol % of the OH groups of the polyvinyl alcohol may be substituted with sulfonic acid groups.

Polyacrylic acid, polyvinyl alcohol partially substituted with a sulfonic acid group, and polyvinylpyrrolidone can further reduce the surface roughness of an aluminum nitride film after polishing. Examples of the hydrophilic polymer having a hydrophilic side chain group other than those described above include a polyacrylic acid-block-poly(ethylene glycol) copolymer.

Although the weight average molecular weight of the hydrophilic polymer is not particularly restricted, it is, for example, 1,000 or more and 1,000,000 or less, preferably 5,000 or more and 500,000 or less, and more preferably 10,000 or more and 200,000 or less. The weight average molecular weight of the hydrophilic polymer can be determined by the method described in Examples described later.

The content (concentration) of the hydrophilic polymer is not particularly limited, and the content of the hydrophilic polymer in the polishing slurry may be 0.001 to 50% by mass, or may be 0.01 to 1% by mass, with respect to 100% by mass of the total mass of the polishing slurry, but the present disclosure is not limited thereto. In some embodiments, when the hydrophilic polymer is polyacrylic acid or polyvinyl alcohol partially substituted with a sulfonic acid group, the polishing slurry may contain the hydrophilic polymer in an amount of 0.01 to 10% by mass, 0.01 to 1% by mass, 0.02 to 0.5% by mass, or 0.02 to 0.05% by mass, with respect to 100% by mass of the total mass of the polishing slurry. When the hydrophilic polymer is polyvinyl alcohol or polyvinylpyrrolidone, the polishing slurry may contain the hydrophilic polymer in an amount of 0.01 to 10% by mass, 0.01 to 1% by mass, 0.02 to 0.5% by mass, or 0.02 to 0.2% by mass, with respect to 100% by mass of the total mass of the polishing slurry.

When an aluminum nitride film is polished using a polishing slurry containing the hydrophilic polymer as described above in the hydrophilic polymer content as described above, the surface roughness of the aluminum nitride film after polishing can be reduced. That is, it becomes possible to make the surface of the aluminum nitride film after polishing using the above-described polishing slurry smoother and/or flatter.

In some embodiments, when the hydrophilic polymer is polyvinylpyrrolidone or polyvinylcaprolactam, the polishing slurry may contain the hydrophilic polymer in an amount of 0.01 to 1.0% by mass, 0.02 to 0.5% by mass, 0.03 to 0.1% by mass, or 0.04 to 0.08% by mass, with respect to 100% by mass of the total mass of the polishing slurry.

When an aluminum nitride film is polished using the polishing slurry containing the hydrophilic polymer as described above in the hydrophilic polymer content as described above, surface defects on the aluminum nitride film after polishing can be reduced.

### [Dispersing Medium]

The polishing slurry of the present disclosure preferably further contains a dispersing medium for dissolving or dispersing the negatively charged abrasive grains, the organic acid compound, and, as necessary, the pH adjusting agent. Examples of the dispersing medium can include: water; alcohols such as methanol, ethanol, and ethylene glycol; ketones such as acetone; and mixtures thereof. Of these, water is preferable as the dispersing medium. According to more preferred embodiment of the present disclosure, the dispersing medium is substantially composed of water. It should be noted that the expression “the dispersing medium is substantially composed of water” described above is intended to mean that a dispersing medium other than water can be contained as long as the object and effects of the present disclosure can be achieved, and more specifically, the dispersing medium is preferably composed of 90% by mass or more and 100% by mass or less of water and 0% by mass or more and 10% by mass or less of a dispersing medium other than water, and is more preferably composed of 99% by mass or more and 100% by mass or less of water and 0% by mass or more and 1% by mass or less of a dispersing medium other than water. Most preferably, the dispersing medium is water.

From the viewpoint of not inhibiting the action of the components contained in the polishing slurry, water containing as few impurities as possible is preferable as the dispersing medium, and specifically, pure water or ultrapure water obtained by removing impurity ions with an ion exchange resin and then passing the water through a filter to remove foreign matter, or distilled water is more preferable.

### <Other Components>

In some embodiments, the polishing slurry of the present disclosure may further contain other components to the extent that the effects of the polishing slurry of the present disclosure are not inhibited. The other components in the polishing slurry are not particularly limited. In some embodiments, the other components in the polishing slurry of the present disclosure may include a wetting agent, a chelating agent, an antiseptic agent, an antifungal agent, a solubilizing agent, a reducing agent, or a combination thereof, but the present disclosure is not limited thereto.

A polishing slurry containing the above-described specific components, namely negatively charged abrasive grains and organic acid compound, in particular, the polishing slurry containing the above-described specific components in the component contents described above, has a high removal rate for aluminum nitride and can reduce the surface roughness of an aluminum nitride film after polishing.

Another aspect of the present disclosure provides a polishing system for a substrate including an aluminum nitride film to be polished. The polishing system includes a polishing pad and a polishing slurry. Since the polishing slurry and the substrate including an aluminum nitride film to be polished are as described above, repeated description thereof will be omitted here. Hereinafter, only the polishing pad will be described.

### <Polishing Pad>

The polishing pad of the present disclosure may include general nonwoven fabric, polyurethane, or porous fluororesin, but the present disclosure is not limited thereto. In some embodiments, the polishing pad may have a Shore A hardness of 10.0 HA or more and 100 HA or less, but the present disclosure is not limited thereto. In some embodiments, the polishing pad may have a Shore A hardness of 10 HA to 90 HA, 12 HA to 70 HA, 14 HA to 50 HA, 16 HA to 30 HA, 18 HA to 28 HA, 20 HA to 26 HA, about 16.5 HA, about 23 HA, or about 24 HA. In some embodiments, the polishing pad may have a Shore D hardness of 70 HD or less, but the present disclosure is not limited thereto. In some embodiments, the polishing pad may have a Shore D hardness of 10 HD to 70 HD, 20 HD to 69 HD, 30 HD to 68 HD, 40 HD to 67 HD, 50 HD to 66 HD, or about 65 HD. A polishing pad having the above-described hardness provides good contact with a substrate including an aluminum nitride film to be polished, and can further increase the surface flatness of the aluminum nitride film after polishing. When a polishing pad having the above-described hardness and the above-described polishing slurry are used together in a polishing process for a substrate including an aluminum nitride film to be polished, the rate of progress of the polishing process can be increased, and the surface flatness of the aluminum nitride film after polishing can be further increased. The Shore A hardness and/or the Shore D hardness may be measured by a Shore (Registered Trademark)(durometer) test in accordance with ASTM D22440-00, ISO 7619, and ISO 868; DIN 53505; and/or JIS K 6301 (replaced by JIS K 6253).

The polishing pad may include a plurality of pores. The pore size of each pore of the polishing pad can be measured by any suitable method. For example, in some embodiments, the pore size of each pore of the polishing pad can be measured by scanning electron microscopy (SEM), and the average pore size can be determined as an arithmetic mean value of the pore sizes. In some embodiments, the average pore size of the plurality of pores is preferably 10 μm or more and 100 μm or less. When the average pore size of the pores of the polishing pad is 100 μm or less, the surface roughness or surface defects of an aluminum nitride film after polishing using the polishing pad can be reduced, which is preferable. When the average pore size of the pores of the polishing pad is, for example, 10 μm or more, slurry is easily retained on the pad surface, and a desired polishing removal rate (polishing rate) can be readily obtained, which is preferable.

In some embodiments, the polishing pad may include a suede pad. In the present disclosure, the term “suede pad” refers to a pad obtained by coating a nonwoven fabric of synthetic fibers with a special polyurethane resin and forming a nap layer by reaction with water. The suede pad is softer than normal urethane pads and nonwoven fabric pads, and reduction in surface roughness can be expected.

In embodiments where the polishing pad includes a suede pad, when the pore size (average pore size) of the nap layer of the suede pad is within the ranges described below, the surface roughness of an aluminum nitride film after polishing can be easily controlled within a preferred range. The pore size of the nap layer of the suede pad is preferably 10 μm or more and 100 μm or less, preferably 20 μm or more and 85 μm or less, preferably 25 μm or more and 75 μm or less, preferably 30 μm or more and 65 μm or less, preferably 35 μm or more and 55 μm or less, and preferably 35 μm or more and 45 μm or less. That is, according to a polishing pad having pores with an average pore size as described above, the surface roughness of an aluminum nitride film after polishing can be further reduced.

The polishing pad described above may be installed on a polishing table of a polishing apparatus. The polishing apparatus is not particularly limited. In some embodiments, the polishing apparatus may be a general polishing apparatus to which a holder for retaining a substrate including an aluminum nitride film and a motor whose rotation speed can be changed are attached, the polishing apparatus having a polishing table to which a polishing pad can be pasted. In some embodiments, the polishing apparatus may be an apparatus capable of carrying out planarization processing and cleaning processing on a substrate including an aluminum nitride film.

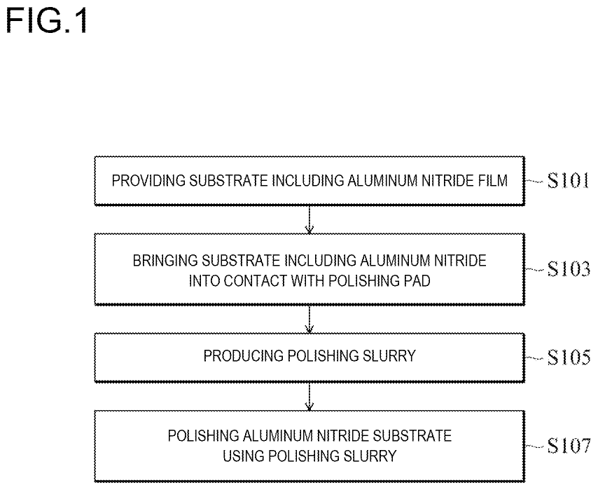

Another aspect of the present disclosure provides a method for polishing a semiconductor substrate. FIG. 1 is a flowchart of a method for polishing a semiconductor substrate according to an embodiment of the present disclosure. As shown in FIG. 1, the polishing method includes: a step S101 of providing a substrate including an aluminum nitride film; a step S103 of bringing the substrate including an aluminum nitride film into contact with a polishing pad; a step S105 of producing a polishing slurry; and a step S107 of polishing the aluminum nitride substrate using the polishing slurry.

The substrate including an aluminum nitride film provided in the step S101 is not particularly limited, as long as the aluminum nitride film in the substrate is exposed to the outside. The substrate including an aluminum nitride film may have a single-layer structure or may have a multilayer structure including a plurality of layers. In some embodiments, since the substrate including an aluminum nitride film provided in the step S101 may have the structure described above, repeated description thereof will be omitted here.

The substrate including an aluminum nitride film provided in the step S101 can be brought into contact with a polishing pad in the step S103. In the step S103, the substrate including an aluminum nitride film can be brought into contact with the polishing pad so that the aluminum nitride film faces the polishing pad. Since the polishing pad in the step S103 may have the structure described above, repeated description thereof will be omitted here. The polishing pad can be installed on a polishing table of a polishing apparatus.

The polishing slurry produced in the step S105 may be as described above. That is, the polishing slurry produced in the step S105 may include negatively charged abrasive grains, an organic acid compound, optionally a pH adjusting agent, optionally a hydrophilic polymer, and optionally other components. Since the negatively charged abrasive grains, the organic acid compound, the pH adjusting agent, the hydrophilic polymer, and the other components are as described above, repeated description thereof will be omitted here. In some embodiments, the polishing slurry produced in the step S105 can be produced using a normal production method at the ratios described above.

In the step S107, when the polishing slurry produced in the step S105 is supplied to the substrate including an aluminum nitride film, a polishing process can proceed. The polishing process is not particularly limited. In some embodiments, the polishing process may include chemical mechanical polishing. Also, the polishing process may be a polishing process constituted by a single step, or may be a polishing process constituted by a plurality of steps. In embodiments where the polishing process is constituted by a plurality of steps, the polishing process may include a process of a pre-polishing step (rough polishing step) and a final polishing step, a primary polishing step, and/or a secondary polishing step after the primary polishing step. Specifically, when the polishing slurry is supplied to the substrate including an aluminum nitride film between the aluminum nitride film and the polishing pad, the polishing process can proceed. The method for supplying the polishing slurry is not particularly limited. In some embodiments, the polishing slurry can be supplied by a continuous method using a pump or the like (flowing). The amount of the polishing slurry to be supplied (the flow rate of the polishing slurry) is not particularly limited either, as long as it is sufficient to cover the substrate including an aluminum nitride film. In some embodiments, the polishing slurry may be supplied at a flow rate of 100 mL/min or more and 5000 mL/min or less, but the present disclosure is not limited thereto.

The polishing load (polishing pressure, processing pressure) used in the polishing process of the step S107 is not particularly limited. In some embodiments, the polishing load used in the polishing process is 0.1 psi or more and 10 psi or less per unit area, but the present disclosure is not limited thereto. In some embodiments, the polishing load used in the polishing process may be 0.5 psi or more and 8 psi or less, or 1 psi or more and 6 psi or less. When the above-described polishing load is used in the polishing process, the removal rate for the aluminum nitride film can be increased, and surface defects on the aluminum nitride film caused by the polishing load can be suppressed.

The rotation speed of the table and the rotation speed of the carrier used in the polishing process of the step S107 are not particularly limited. In some embodiments, the rotation speed of the table and the rotation speed of the carrier used in the polishing process may each be 10 rpm or more and 500 rpm or less, but the present disclosure is not limited thereto. In some embodiments, the rotation speed of the table and the rotation speed of the carrier used in the polishing process may each be 20 rpm or more and 300 rpm or less, or 30 rpm or more and 200 rpm or less.

The polishing time employed in the polishing process of the step S107 is not particularly limited, as long as it is a time by which a desired polishing result can be obtained. In some embodiments, the polishing time employed in the polishing process of the step S107 may be 5 seconds or longer and 180 seconds or shorter, but the present disclosure is not limited thereto.

In some embodiments, the method for polishing a semiconductor substrate of the present disclosure may further include a substrate cleaning step and a substrate drying step after the step S107. In some embodiments, the substrate cleaning step may include cleaning the substrate with running water, and the substrate drying step may include drying the substrate by blowing off water droplets adhering to the substrate using a spin dryer.

The above-described method for polishing a semiconductor substrate using the polishing slurry and the polishing pad can achieve a high removal rate for aluminum nitride and can also reduce the surface roughness of an aluminum nitride film after polishing.

It should be noted that the following items are also included within the scope of the present disclosure.
1. A polishing slurry for a substrate including an aluminum nitride film to be polished, the polishing slurry containing:
   negatively charged abrasive grains; and
   an organic acid compound.
2. The polishing slurry according to the above 1., further containing a pH adjusting agent.
3. The polishing slurry according to the above 1, or 2., wherein the polishing slurry contains 0.1 to 10% by mass of the negatively charged abrasive grains and 0.01 to 3% by mass of the organic acid compound with respect to 100% by mass of a total mass of the polishing slurry.
4. The polishing slurry according to any of the above 1. to 3., wherein the polishing slurry has a pH value of more than 4 and 8 or less.
5. The polishing slurry according to any of the above 1. to 4., further containing a hydrophilic polymer, wherein the hydrophilic polymer has at least one hydrophilic side chain group.
6. The polishing slurry according to the above 5., wherein the at least one hydrophilic side chain group includes a hydroxy group, an acryloyl group, a sulfonic acid group, a pyrrolidone group, a caprolactam group, or a combination thereof.
7. The polishing slurry according to any of the above 1. to 6., further containing a hydrophilic polymer, wherein the hydrophilic polymer includes polyvinylpyrrolidone, polyvinylcaprolactam, or a combination thereof.
8. The polishing slurry according to any of the above 1. to 7., wherein the organic acid compound includes an ammonium salt.
9. The polishing slurry according to the above 8., wherein the organic acid compound contains at least two carboxyl groups.
10. The polishing slurry according to any of the above 1. to 9., further containing a pH adjusting agent, wherein the pH adjusting agent includes a monocarboxylic acid.
11. The polishing slurry according to any of the above 1. to 10., wherein the negatively charged abrasive grains include sulfonic acid-modified silica.
12. A polishing system for a substrate including an aluminum nitride film to be polished, the polishing system containing:
   a polishing pad; and
   a polishing slurry,
wherein the polishing slurry contains:
   negatively charged abrasive grains; and
   an organic acid compound.
13. The polishing system according to the above 12., wherein the polishing slurry further contains a pH adjusting agent.
14. The polishing system according to the above 12. or 13., wherein the polishing pad has a Shore A hardness of 10.0 HA or more and 100 HA or less.
15. The polishing system according to any of the above 12. to 14., wherein the polishing pad has a Shore D hardness of 70 HD or less.
16. The polishing system according to any of the above 12. to 15., wherein the polishing pad has a plurality of pores, and the plurality of pores has an average pore size of 10 μm or more and 100 μm or less.
17. A method for polishing a semiconductor substrate, the method including the steps of:
   providing a substrate including an aluminum nitride film;
   bringing the substrate including an aluminum nitride film into contact with a polishing pad;
   producing a polishing slurry; and
   polishing the substrate including an aluminum nitride film using the polishing slurry,
   wherein the polishing slurry contains:
   negatively charged abrasive grains; and
   an organic acid compound.
18. The method for polishing a semiconductor substrate according to the above 17., wherein the polishing slurry further contains a pH adjusting agent.

Hereinafter, the contents disclosed herein will be described in even further detail by way of Examples and Comparative Examples. However, the technical scope of the present disclosure is not limited only to the following Examples. Unless otherwise specified, “%” refers to “% by mass”. Furthermore, in the following Examples and Comparative Examples, unless otherwise specified, all polishing operations in the polishing process were carried out at room temperature (20 to 25° C.) and a relative humidity of 40 to 50% RH.

### <Object to be Polished>

A 300 mm silicon wafer on which an aluminum nitride film having a thickness of 5000 Å is deposited by a physical vapor deposition (PVD) method.

### <Polishing Apparatuses>

CMP polishing machine (manufactured by Ebara Corporation, product name: FREX 300SII)

### <Dresser>

Diamond dresser (manufactured by 3M Company, product name: A188)

### <Polishing Pad>

Polishing pad A: having a Shore D hardness of 65 D and including a plurality of pores with an average pore size of 10 μm or more and 100 μm or less (purchased from DuPont de Nemours, Inc., product name: IC1010 (Registered Trademark)).

Polishing pad B: having a Shore A hardness of 23 A and including a plurality of pores with an average pore size of 37.3 μm (purchased from Fujibo Precision Materials Co., Ltd., product name: POLYPAS (Suede) H800).

Polishing pad C: having a Shore A hardness of 16.5 A and including a plurality of pores with an average pore size of 31.2 μm (purchased from Fujibo Precision Materials Co., Ltd., product name: POLYPAS (Suede) H804).

Polishing pad D: having a Shore A hardness of 24 A and including a plurality of pores with an average pore size of 47.7 μm (purchased from Fujibo Precision Materials Co., Ltd., product name: POLYPAS (Suede) H600).

### <Hydrophilic Polymer>

Hydrophilic polymer A: polyvinyl alcohol having a weight average molecular weight of 10,000.
Hydrophilic polymer B: polyacrylic acid having a weight average molecular weight of 200,000.
Hydrophilic polymer C: substituted polyvinyl alcohol having a weight average molecular weight of 40,000 (5 mol % of OH groups are substituted with sulfonic acid groups (—SO₃H)).
Hydrophilic polymer D: polyvinylpyrrolidone (PVP) having a weight average molecular weight of 40,000.

It should be noted that, in the present specification, the weight average molecular weight is measured by gel permeation chromatography (GPC) using polystyrene having a known molecular weight as a reference substance.

### Production of Polishing Slurry

### Example 1

By coupling 3-mercaptopropyltrimethoxysilane (a silane coupling agent having a thiol group) to colloidal silica and then oxidizing the thiol group with hydrogen peroxide, colloidal silica having sulfonic acid immobilized on the surface thereof as abrasive grains A was provided. Then, ultrapure water was added to the abrasive grains A to obtain an 0.5 L of an abrasive grain slurry containing the abrasive grains A (4 mass % slurry). The abrasive grains A are negatively charged abrasive grains of the present disclosure.

The silanol group density of the abrasive grains A was 5.3 groups/nm². Using a laser light scattering measurement apparatus (manufactured by Malvern Panalytical, Ltd., product name: Zetasizer Ultra), it was measured that the average secondary particle size of the abrasive grains A was 70 nm. In addition, the number of silanol groups per unit surface area of the abrasive grains A was calculated by the Sears method using neutralization titration described by G. W. Sears in Analytical Chemistry, vol. 28, No. 12, 1956, pp. 1982-1983.

To 1.0 g of ammonium citrate tribasic (H₄NOCOCH₂C(OH)(COONH₄)CH₂COONH₄), which is an organic acid compound, was added 0.1 kg of ultrapure water, which was stirred to obtain a second mixture. The second mixture was added to the above-described abrasive grain slurry. Acetic acid, which is a pH adjusting agent, and ultrapure water were added in arbitrary amounts to adjust a final mass to 1 kg, thereby obtaining a polishing slurry 1. In the polishing slurry 1, the concentration of the abrasive grains A was 2% by mass, and the concentration of ammonium citrate tribasic was 0.1% by mass. It should be noted that the pH of the polishing slurry 1 was adjusted by controlling an addition amount of the pH adjusting agent so as to achieve the value described in Table 1 below.

### Example 2, Comparative Examples 3 and 4, and Examples 5 to 8 and 15 to 19

Polishing slurries 2 to 8 and 15 to 19 of Example 2, Comparative Examples 3 and 4, and Examples 5 to 8 and 15 to 19 were obtained by the same method as in Example 1, except that the components and contents listed in Table 1 were different. It should be noted that the pH of the polishing slurries 2 to 8 and 15 to 19 was adjusted by controlling an addition amount of the pH adjusting agent so as to achieve the values described in Table 1 below.

### Examples 9 to 14, 20, and 21

In Example 1, the content of the abrasive grains A in the abrasive grain slurry was changed to 1% by mass. Next, a second mixture was prepared in the same manner as in Example 1, and the second mixture was added to the abrasive grain slurry to prepare a third mixture. To the hydrophilic polymers listed in Table 1 was added 0.1 kg of ultrapure water, thereby preparing a fourth mixture. At this time, the amount of the hydrophilic polymer to be added was set to such an amount that the concentration thereof in the polishing slurry finally obtained became the value described in Table 1. The third mixture was stirred and added to the fourth mixture. Acetic acid and ultrapure water were added in arbitrary amounts to adjust a final mass to 1 kg, thereby obtaining polishing slurries 9 to 14, 20, and 21. It should be noted that the pH of the polishing slurries 9 to 14, 20, and 21 was adjusted by controlling an addition amount of the pH adjusting agent so as to achieve the values described in Table 1 below.

The components used to produce the above-described polishing slurries 1 to 21 and the contents of the respective components were summarized in Table 1. In Table 1, the content of each component represents a content (% by mass) with respect to 100% by mass of the total mass of the polishing slurry. Using a pH meter (manufactured by HORIBA, Ltd., product name: LAQUA), the pH values of the polishing slurries 1 to 21 were confirmed (the temperature of the polishing slurry at the time of pH value measurement was 25° C.). The pH values of the above-described polishing slurries 1 to 21 are shown in Table 1. The zeta potential of the abrasive grains in the polishing slurries 1 to 21 was measured using a zeta potential measuring apparatus and confirmed that the abrasive grains in the polishing slurries 1 to 21 were negatively charged.

TABLE 1

| | | | | | | | | pH | |
|---|---|---|---|---|---|---|---|---|---|
| | | Negatively charged | Concentration | Organic acid | Concentration | Hydrophilic | Concentration | adjusting | pH |
| Polishing slurry | | abrasive grains | (% by mass) | compound | (% by mass) | polymer | (% by mass) | agent | value |
| Polishing | Inventive | Negatively charged | 2 | Ammonium | 0.1 | — | — | Acetic | 6.0 |
| slurry 1 | | abrasive grains A | | citrate tribasic | | | | acid | |
| Polishing | Inventive | Negatively charged | 2 | Ammonium | 0.2 | — | — | Acetic | 6.0 |
| slurry 2 | | abrasive grains A | | citrate tribasic | | | | acid | |
| Polishing | Comparative | Negatively charged | 2 | Ammonium | 0.1 | — | — | Acetic | 6.0 |
| slurry 3 | | abrasive grains A | | sulfate | | | | acid | |
| Polishing | Comparative | Negatively charged | 2 | Ammonium | 0.2 | — | — | Acetic | 6.0 |
| slurry 4 | | abrasive grains A | | sulfate | | | | acid | |
| Polishing | Inventive | Negatively charged | 2 | Ammonium | 0.1 | — | — | Nitric | 6.0 |
| slurry 5 | | abrasive grains A | | citrate tribasic | | | | acid | |
| Polishing | Inventive | Negatively charged | 2 | Ammonium | 0.1 | — | — | Malonic | 6.0 |
| slurry 6 | | abrasive grains A | | citrate tribasic | | | | acid | |
| Polishing | Inventive | Negatively charged | 2 | Ammonium | 0.1 | — | — | Citric | 6.0 |
| slurry 7 | | abrasive grains A | | citrate tribasic | | | | acid | |
| Polishing | Inventive | Negatively charged | 1 | Ammonium | 0.1 | — | — | Acetic | 6.0 |
| slurry 8 | | abrasive grains A | | citrate tribasic | | | | acid | |
| Polishing | Inventive | Negatively charged | 1 | Ammonium | 0.1 | Hydrophilic | 0.05 | Acetic | 6.0 |
| slurry 9 | | abrasive grains A | | citrate tribasic | | polymer A | | acid | |
| Polishing | Inventive | Negatively charged | 1 | Ammonium | 0.1 | Hydrophilic | 0.025 | Acetic | 6.0 |
| slurry 10 | | abrasive grains A | | citrate tribasic | | polymer B | | acid | |
| Polishing | Inventive | Negatively charged | 1 | Ammonium | 0.1 | Hydrophilic | 0.025 | Acetic | 6.0 |
| slurry 11 | | abrasive grains A | | citrate tribasic | | polymer C | | acid | |
| Polishing | Inventive | Negatively charged | 1 | Ammonium | 0.1 | Hydrophilic | 0.025 | Acetic | 6.0 |
| slurry 12 | | abrasive grains A | | citrate tribasic | | polymer D | | acid | |
| Polishing | Inventive | Negatively charged | 1 | Ammonium | 0.1 | Hydrophilic | 0.05 | Acetic | 6.0 |
| slurry 13 | | abrasive grains A | | citrate tribasic | | polymer D | | acid | |
| Polishing | Inventive | Negatively charged | 1 | Ammonium | 0.1 | Hydrophilic | 0.1 | Acetic | 6.0 |
| slurry 14 | | abrasive grains A | | citrate tribasic | | polymer D | | acid | |
| Polishing | Inventive | Negatively charged | 1 | Ammonium | 0.1 | — | — | Acetic | 4.0 |
| slurry 15 | | abrasive grains A | | citrate tribasic | | | | acid | |
| Polishing | Inventive | Negatively charged | 1 | Ammonium | 0.1 | — | — | Acetic | 5.0 |
| slurry 16 | | abrasive grains A | | citrate tribasic | | | | acid | |
| Polishing | Inventive | Negatively charged | 1 | Ammonium | 0.1 | — | — | Acetic | 7.0 |
| slurry 17 | | abrasive grains A | | citrate tribasic | | | | acid | |
| Polishing | Inventive | Negatively charged | 1 | Ammonium | 0.1 | — | — | Acetic | 7.5 |
| slurry 18 | | abrasive grains A | | citrate tribasic | | | | acid | |
| Polishing | Inventive | Negatively charged | 1 | Ammonium | 0.1 | — | — | Acetic | 8.0 |
| slurry 19 | | abrasive grains A | | citrate tribasic | | | | acid | |
| Polishing | Inventive | Negatively charged | 1 | Ammonium | 0.1 | Hydrophilic | 0.05 | Acetic | 6.0 |
| slurry 20 | | abrasive grains A | | citrate tribasic | | polymer D | | acid | |
| Polishing | Inventive | Negatively charged | 1 | Ammonium | 0.1 | Hydrophilic | 0.05 | Acetic | 6.0 |
| slurry 21 | | abrasive grains A | | citrate tribasic | | polymer D | | acid | |

As shown in Table 2 below, using the above-described polishing slurries 1 to 21 and the polishing pads A to D, a polishing process was carried out on the above-described object to be polished under the conditions described below by means of the above-described polishing apparatus and dresser.

### <Polishing Conditions>

Polishing time for aluminum nitride film: 60 seconds
Polishing table pressure: 70 hPa (1 psi)
Rotation speed of polishing table: 90 rpm
Rotation speed of carrier: 91 rpm
Supply rate of polishing slurry: 300 ml/min.

### <Dressing Conditions>

Before carrying out the above-described polishing of aluminum nitride film, dressing of the polishing pad was carried out using pure water under the following conditions. It should be noted that the polishing apparatus, polishing pad, and dresser used were the same as those in the above-described polishing conditions.
Rotation speed of polishing table during dressing: 90 rpm
Pressure applied by dresser to polishing table (polishing pad): 22 N
Dressing time: ex-situ 15 seconds
Flow rate of pure water supplied during dressing: 2,000 ml/min.

### <Measurement of Surface Roughness>

The center line average roughness (Ra) of the aluminum nitride film after polishing was measured using an atomic force microscope manufactured by Bruker, Dimension ICON. Using the OTESPA-R4 probe manufactured by Bruker, the surface roughness of the aluminum nitride film after polishing was measured in a field of view of 2 μm, at a scanning speed of 0.5 Hz, and within a Z range of −2 to 2 nm. If the surface roughness is 1 nm or less, it can be used without problems; a surface roughness of 0.5 nm or less is preferable, and less than 0.5 nm is more preferable.

### <Measurement of Removal Rate for Aluminum Nitride>

The film thickness of the aluminum nitride film before and after polishing was measured using a sheet resistance type film thickness measurement apparatus (RS-100 manufactured by KLA-Tencor Corporation). The removal rate for aluminum nitride was calculated using the difference in thickness of the aluminum nitride film before and after polishing. If the removal rate is more than 500 Å/min, it can be used without problems; a removal rate of more than 1000 Å/min is preferable.

### <Measurement of Surface Defects>

The surface defects on the aluminum nitride film after polishing were measured using an atomic force microscope manufactured by Bruker, Dimension ICON. Using the OTESPA-R4 probe manufactured by Bruker, surface defects with a depth of 0.3 nm or more were measured in a field of view of 2 μm, at a scanning speed of 0.5 Hz, and within a Z range of −3 to 3 nm, and the number of surface defects was calculated. If the surface defects are less than 5000 counts/cm², it can be used without problems.

The measurement results of the above-described surface roughness, removal rate for aluminum nitride, and number of surface defects are shown in Table 2 below. In Table 2, N/A indicates that data were not obtained (no data available).

TABLE 2

| | | | Surface roughness | Removal rate | Surface defects |
|---|---|---|---|---|---|
| Polishing slurry | | Polishing pad | (nm) | (Å/min) | (counts/cm²) |
| Polishing slurry 1 | Inventive | Polishing pad A | 0.34 | 1135 | N/A |
| Polishing slurry 2 | Inventive | Polishing pad A | 0.28 | 1301 | N/A |
| Polishing slurry 3 | Comparative | Polishing pad A | 16.32 | 1130 | N/A |
| Polishing slurry 4 | Comparative | Polishing pad A | 11.17 | 2129 | N/A |
| Polishing slurry 5 | Inventive | Polishing pad A | 0.28 | 877 | N/A |
| Polishing slurry 6 | Inventive | Polishing pad A | 0.41 | 978 | N/A |
| Polishing slurry 7 | Inventive | Polishing pad A | 0.36 | 842 | N/A |
| Polishing slurry 8 | Inventive | Polishing pad B | 0.25 | 3916 | 4333 |
| Polishing slurry 9 | Inventive | Polishing pad B | 0.25 | 3057 | 4445 |
| Polishing slurry 10 | Inventive | Polishing pad B | 0.18 | 4002 | 4548 |
| Polishing slurry 11 | Inventive | Polishing pad B | 0.17 | 3149 | 4563 |
| Polishing slurry 12 | Inventive | Polishing pad B | 0.25 | 3003 | 2730 |
| Polishing slurry 13 | Inventive | Polishing pad B | 0.24 | 2936 | 2186 |
| Polishing slurry 14 | Inventive | Polishing pad B | 0.27 | 2421 | 2746 |
| Polishing slurry 15 | Inventive | Polishing pad B | 0.50 | 4293 | N/A |
| Polishing slurry 16 | Inventive | Polishing pad B | 0.30 | 4597 | N/A |
| Polishing slurry 17 | Inventive | Polishing pad B | 0.25 | 3132 | N/A |
| Polishing slurry 18 | Inventive | Polishing pad B | 0.29 | 3031 | N/A |
| Polishing slurry 19 | Inventive | Polishing pad B | 0.31 | 2648 | N/A |
| Polishing slurry 20 | Inventive | Polishing pad C | 0.37 | 3752 | N/A |
| Polishing slurry 21 | Inventive | Polishing pad D | 0.26 | 2854 | N/A |

As can be seen from Tables 1 and 2 above, the polishing slurries 1, 2, and 5 to 21 of the present disclosure contain negatively charged abrasive grains and an organic acid compound. When the above-described polishing slurries 1, 2, and 5 to 21 were used to polish a substrate including an aluminum nitride film, they increased the removal rate for aluminum nitride while reducing the surface roughness of the aluminum nitride film after polishing.

Specifically, as can be seen from Table 2 above, when the polishing slurries 1, 2, and 5 to 21 were used to polish a substrate including an aluminum nitride film, they exhibited an excellent removal rate for aluminum nitride of 800 Å/min or more. In addition, the surface roughness of the aluminum nitride film after polishing was reduced to a surface roughness of 0.5 nm or less. In contrast, when the polishing slurries 3 and 4, which do not contain an organic acid compound, were used to polish a substrate including an aluminum nitride film, the surface roughness could not be sufficiently reduced.

In particular, the polishing slurries 1, 2, and 8 to 21, which contain a monocarboxylic acid as a pH adjusting agent, exhibited a higher removal rate for aluminum nitride (for example, a removal rate of higher than 1000 Å/min) when used to polish a substrate including an aluminum nitride film. In addition, the polishing slurries 1, 2, and 5 to 21 of the present disclosure resulted in a sufficiently low surface roughness of the aluminum nitride film after polishing when used to polish a substrate including an aluminum nitride film (for example, a surface roughness of 0.5 nm or less). The polishing slurries 8 to 14 of the present disclosure resulted in sufficiently low surface defects of the aluminum nitride after polishing when used to polish a substrate including an aluminum nitride film (for example, surface defects of less than 5000 counts/cm²).

Furthermore, when the organic acid compound in the polishing slurry is a carboxylic acid salt, the surface roughness of the aluminum nitride film after polishing can be further reduced. Among the polishing slurries using a carboxylic acid salt as the organic acid compound, it was found that when the pH value of the polishing slurry is more than 4, the surface roughness of the aluminum nitride film after polishing is further reduced.

In summary, the polishing slurry of the present disclosure has a high removal rate for aluminum nitride and can also reduce the surface roughness of the aluminum nitride film after polishing. When a polishing pad having a moderate hardness is used together with the polishing slurry of the present disclosure to polish a substrate including an aluminum nitride film, the removal rate for aluminum nitride can be increased while reducing the surface roughness of the aluminum nitride film after polishing.

Although the embodiments of the present disclosure and advantages thereof have been disclosed as described above, it should be understood that, as long as they do not depart from the spirit and scope of the present disclosure, modifications, substitutions, and alterations can be made by a person having ordinary skill in the art. In addition, the scope of protection of the present disclosure is not limited only to the processes, equipment, manufacture, compositions of substances, apparatuses, and steps in the specific embodiments described in the present specification. A person having ordinary skill in the art can understand, from the disclosed contents of some embodiments of the present disclosure, processes, equipment, manufacture, compositions of substances, apparatuses, and steps that are existing or may be developed in the future, and all of these can be used based on the embodiments of the present disclosure as long as they can conduct substantially the same functions or can achieve substantially the same results as those in the embodiments described in the present specification. Accordingly, the scope of protection of the present disclosure includes these processes, equipment, manufacture, compositions of substances, apparatuses, and steps as well. In addition, each embodiment can complete other embodiments by replacing, combining, or mixing characteristics in a plurality of different embodiments, as long as they do not depart from the spirit of the present disclosure. The characteristics among the embodiments can be used in any combination, as long as they do not contradict the spirit of the present disclosure or conflict with each other. Each claim constitutes an individual embodiment, and the scope of protection of the present disclosure includes combinations of the claims and embodiments.

The present application is based on Japanese Patent Application No. 2025-049815 filed on Mar. 25, 2025, and the contents disclosed therein are incorporated herein by reference in their entirety.

### REFERENCE SIGNS LIST

S101, S103, S105, and S107 . . . steps

1. A polishing slurry for a substrate including an aluminum nitride film to be polished, the polishing slurry comprising:
negatively charged abrasive grains; and
an organic acid compound.

2. The polishing slurry according to claim 1, wherein the polishing slurry comprises 0.1 to 10% by mass of the negatively charged abrasive grains and 0.01 to 3% by mass of the organic acid compound with respect to 100% by mass of a total mass of the polishing slurry.

3. The polishing slurry according to claim 1, wherein the polishing slurry has a pH value of more than 4 and 8 or less.

4. The polishing slurry according to claim 1, further comprising a hydrophilic polymer, wherein the hydrophilic polymer has at least one hydrophilic side chain group.

5. The polishing slurry according to claim 4, wherein the at least one hydrophilic side chain group includes a hydroxy group, an acryloyl group, a sulfonic acid group, a pyrrolidone group, a caprolactam group, or a combination thereof.

6. The polishing slurry according to claim 4, further comprising a hydrophilic polymer, wherein the hydrophilic polymer includes polyvinylpyrrolidone, polyvinylcaprolactam, or a combination thereof.

7. The polishing slurry according to claim 1, wherein the organic acid compound includes an ammonium salt.

8. The polishing slurry according to claim 7, wherein the organic acid compound contains at least two carboxyl groups.

9. The polishing slurry according to claim 1, further comprising a pH adjusting agent, wherein the pH adjusting agent includes a monocarboxylic acid.

10. The polishing slurry according to claim 1, wherein the negatively charged abrasive grains include sulfonic acid-modified silica.

11. A polishing system for a substrate including an aluminum nitride film to be polished, the polishing system comprising:
a polishing pad; and
a polishing slurry,
wherein the polishing slurry comprises:
negatively charged abrasive grains; and
an organic acid compound.

12. The polishing system according to claim 11, wherein the polishing pad has a Shore A hardness of 10.0 HA or more and 100 HA or less.

13. The polishing system according to claim 11, wherein the polishing pad has a Shore D hardness of 70 HD or less.

14. The polishing system according to claim 11, wherein the polishing pad has a plurality of pores, and the plurality of pores has an average pore size of 10 μm or more and 100 μm or less.

15. A method for polishing a semiconductor substrate, the method comprising the steps of:
providing a substrate including an aluminum nitride film;
bringing the substrate including an aluminum nitride film into contact with a polishing pad;
producing a polishing slurry; and
polishing the substrate including an aluminum nitride film using the polishing slurry,
wherein the polishing slurry comprises:
negatively charged abrasive grains; and
an organic acid compound.
